(19) United States
(12) Patent Application Publication
(10) Pub. No.: US 2003/0219919 A1
(43) Pub. Date: Nov. 27, 2003

(54) Package method for enhancing the brightness of LED

(76) Inventors: Der-nan Wang, Chia-I (TW); Lung-hsin Chen, Hsin-chu (TW)

Correspondence Address: MARTINE & PENILLA, LLP, 710 LAKEWAY DRIVE, SUITE 170, SUNNYVALE, CA, 94085, US

(21) Appl. No.: 10/255,877

(22) Filed: Sep. 25, 2002

(30) Foreign Application Priority Data
May 23, 2002 (TW) 91110992

(51) Int. Cl. H01L 21/00

(52) U.S. Cl. 438/26

(57) ABSTRACT

The invention provides a package method for enhancing the brightness of an LED, and the package method comprises the following steps: planarizing a surface of the mount; forming a reflection mirror on the surface of the mount; and attaching an LED chip to the mount.

### BACKGROUND OF THE INVENTION

1. Field of the Invention

The invention relates to a package method for an LED and, more particularly, to a package method that utilizes a planarization process to enhance the brightness of an LED.

2. Description of the Related Art

The light emitted by an LED (Light-emitting Diode) tends to be confined by the packaging structure of the LED itself. For example, the light that an LED emits toward a substrate is obstructed by the packaging structure of the substrate; therefore, the light emitted in such orientation cannot be well utilized. Hence, it is difficult to enhance the efficiency of light emitting and emitting intensity.

As shown in FIG. 1, the conventional packaging technique is first to coat a circuit board 101 with a metal conductive layer 102, which is described in Taiwan Patent Publication No. 474030 titled “The package method for LED”. Next, the metal conductive layer 102, together with the circuit board 101, is divided and formed into a positive electrode 102A and a negative electrode 102B, as shown in FIG. 1B. Then, an LED chip 103 is attached to the electrodes 102A and 102B. Finally, they are sealed with resin 104.

As to the foregoing conventional LED package method, since the conductive layer 102 that is used to form electrodes is made of metal, the metal conductive layer 102 may also be effective in light reflecting. However, because the conventional package method is to plate the circuit board 101 with the metal conductive layer 102 directly, and because the circuit board 101 contains surface cavities and has a certain degree of coarseness, the metal conductive layer 102 coated on the circuit board 101 becomes very uneven. Therefore, when the light of LED incidents on the surface of the uneven metal conductive layer 102, a large amount of light is diffused and absorbed; consequently, the reflectivity is decreased tremendously, making the light that is reflected by the metal conductive layer to the emitting orientation weaken, and making it difficult to get the expected result of enhancing the efficiency of light emitting and emitting intensity.

### SUMMARY OF THE INVENTION

The object of the invention is to provide a package method that enhances the brightness of an LED, wherein by utilizing a reflection mirror that has been formed through planarization, the brightness of an LED can be largely enhanced.

One embodiment of the invention includes the following steps: the first step is to provide a mount and then planarize a surface of the mount; the second step is to form a reflection mirror on the surface of the mount; and the last step is to attach an LED chip to the mount.

The above-mentioned planarization can be accomplished by using the method of transfer printing, spraying, blushing, dipping, or chemical mechanical polishing.

In addition, the reflection mirror can be formed by metal sputtering or evaporation, and the LED chip can be attached to the mount by surface mounting.

Another embodiment of the invention commences with the step of providing a mount with a recess, and the second step is to planarize the recess of the mount. Finally, the last step is to form a reflection mirror on the surface of the recess, and subsequently attach an LED chip to the inside of the recess of the mount.

Also, an extrusion can be formed at the inside of the recess of the mount, and if the LED chip is attached to the extrusion, a optimum incident angle to the reflection mirror can be formed.

In still another embodiment of the invention, the method further includes the following steps: the first step is to planarize the surface of the mount; the second step is to form electrodes on the surface of the mount; the third step is to attach an LED chip to the mount; and the last step is to install a block member with a reflection mirror, which has been formed through the planarization, on the surface of the mount. Since the block member that has a metal reflection mirror can be allocated differently in accordance with the different positions of the LED chip and can be manufactured in different shapes, it is then easier to optimize the reflection mirror of the invention.

When packaging an LED in the invention, the step of planarizing the mount so as to form a smooth surface of the mount enables the reflection mirror, which subsequently deposits on the surface, to form a smooth surface evenly so that the reflectivity of the reflection mirror can be largely increased. When the smooth reflection mirror is formed on the mount, the light that is emitted from the LED toward the mount will be reflected to the light emitting orientation by the reflection mirror of high reflectivity of the invention. Therefore, the efficiency of light emitting is largely improved, and the brightness of an LED can then be enhanced.

### BRIEF DESCRIPTION OF THE DRAWINGS

FIGS. 1A and 1B are sectional schematic diagrams showing the process of conventional LED package method.

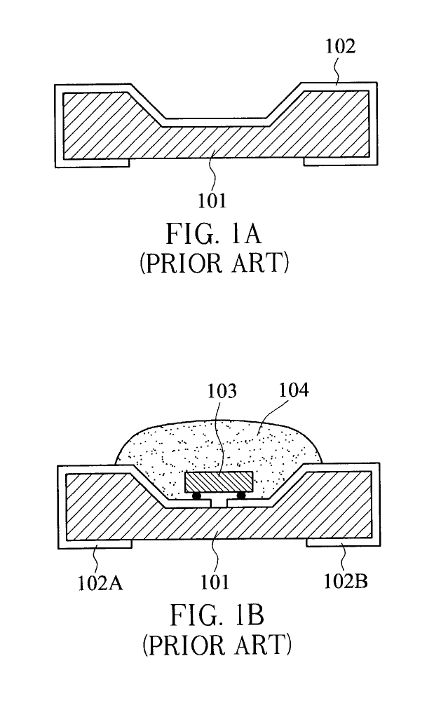

FIGS. 2A to 2C are sectional diagrams showing each step of the package method for enhancing the brightness of an LED according to an embodiment of the invention.

FIGS. 3A to 3D are sectional diagrams showing each step of the package method for enhancing the brightness of an LED according to another embodiment of the invention.

FIGS. 4A to 4C are sectional diagrams showing each step of the package method for enhancing the brightness of an LED according to still another embodiment of the invention.

### DESCRIPTION OF THE PREFERRED EMBODIMENTS

The following will describe the embodiments of the invention with reference to the accompanied drawings.

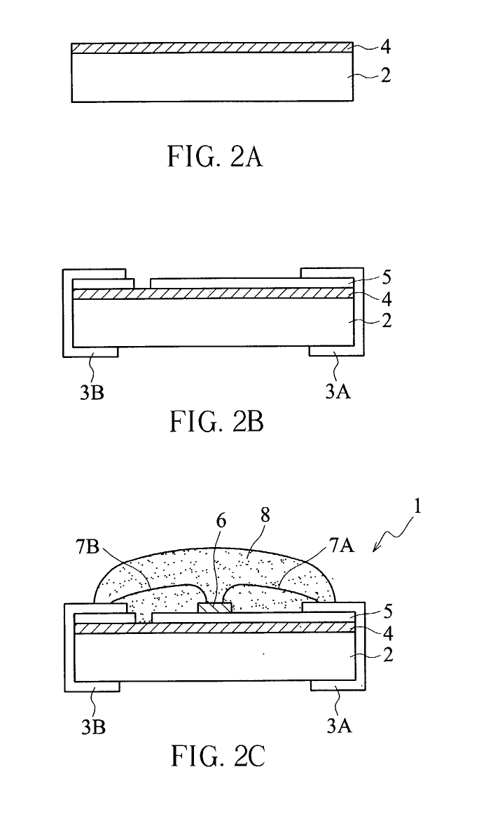

FIGS. 2A to 2C are sectional diagrams showing each step of the package method for enhancing the brightness of an LED according to an embodiment of the invention. First, a mount 2 is used as a package stem for the LED, as shown in FIG. 2A. The material for the mount 2 can be a ceramic substrate or other insulating materials. Next, planarizing the mount 2 by forming a leveling layer 4 on the surface of the mount 2, and the leveling layer 4 can be formed by the method of dipping, transfer printing, blushing or spraying. The leveling layer 4 can fill the cavities or holes that the material of the mount 2 contains on its surface and planarize the surface of the mount 2. Then, by thin film deposition such as metal sputtering or evaporation, the leveling layer 4 is plated with the metal that can reflect light, and a metal reflection mirror 5 is formed on the mount 2. Furthermore, by the method of dipping, metal evaporation or sputtering, transfer printing or blushing, opposed electrodes 3A and 3B are formed on the two ends of the mount 2. As shown in FIG. 2B, the formation of the reflection mirror 5 is to deposit on the surface that has been planarized (i.e., on the leveling layer 4) so that a fairly smooth reflection mirror can be obtained.

In addition, the LED chip 6 is attached to the metal reflection mirror 5 by the method of surface mounting, as shown in FIG. 2C. Then, by wire bonding, the LED chip 6 is electrically connected to the electrodes 3A and 3B through the wires 7A and 7B. Finally, by the method of epoxy encapsulating, the LED chip 6 is covered with the resin 8 to prevent from contacting the outside oxygen or moisture, and thereby the LED package 1 of the invention is completed.

When the degree of coarseness of the surface is high or the holes on the surface is large, the light that incidents on the surface is easy to be diffused or absorbed, making the intensity of the reflected light decreased tremendously. The invention is first to planarize the mount 2 to form a smooth surface for the mount, so the reflection mirror, which subsequently deposits on the surface, is able to form a smooth surface evenly in order that the reflectivity of the reflection mirror can be largely increased. When the mount 2 is firstly formed with the evenly surface through the above-mentioned planarization process and then a smooth reflection mirror is formed on the mount 2, the light that is emitted from the LED toward the mount 2 can mostly be reflected to the desired light emitting orientation so as to be fully utilized. Hence, the efficiency of light emitting of an LED can be largely increased, and the brightness of an LED can then be enhanced.

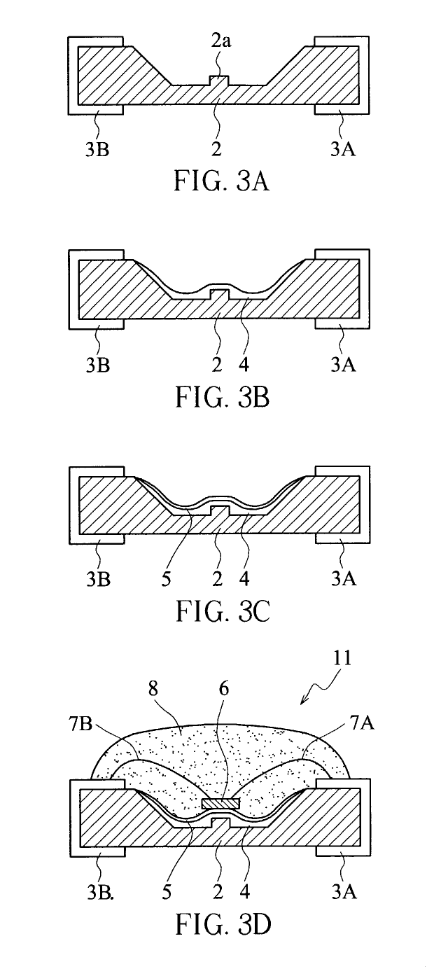

FIGS. 3A to 3D are sectional diagrams showing each step of the package method for enhancing the brightness of an LED according to another embodiment of the invention.

As shown in FIG. 3A, a mount 2 with a recess is used as a package stem for the LED according to this embodiment. The material for the mount 2 can also be a ceramic substrate or insulating materials, and inside the recess of the mount 2 there further forms an extrusion 2a. Next, by the method of dipping, metal evaporation or sputtering, transfer printing or blushing, opposed electrodes 3A and 3B are formed on the two ends of the mount 2.

As shown in FIG. 3B, the planarization according to this embodiment is to form a leveling layer 4 on the surface of the inside recess of the mount 2. The leveling layer 4 can be formed on the surface of the inside recess of the mount 2 by the method of dipping, transfer printing, blushing, or spraying. Furthermore, by thin film deposition such as metal sputtering or evaporation, the leveling layer 4 is plated with the metal that can reflect light, and thus a metal reflection mirror 5 is formed inside the recess of the mount 2, as shown in FIG. 3C. The formation of the reflection mirror 5 is to deposit on the surface that has been planarized (i.e., on the leveling layer 4), so that a fairly smooth reflection mirror can be obtained.

Then, by wire bonding, the LED chip 6 is electrically connected to the electrodes 3A and 3B through the wires 7A and 7B. Finally, by the method of epoxy encapsulating, the LED chip 6 is covered with the resin 8, and thereby the LED package 11 of the invention is completed as shown in FIG. 3D.

Since an extrusion 2a is formed inside the recess of the mount 2 according to this embodiment, the extrusion 2a can provide the LED chip 6 with certain height when the LED chip 6 is attached to the metal reflection mirror 5 on the extrusion 2a, which makes the light-receiving area of the metal reflection mirror 5 that receives the light emitted from the LED increase. Therefore, while the mount 2 is formed, the optimum height of the extrusion 2a can be selected at the same time. Hence, a good incident angle can be formed when the LED emits light toward the metal reflection mirror 5 so that the largest amount of light emitting can be obtained.

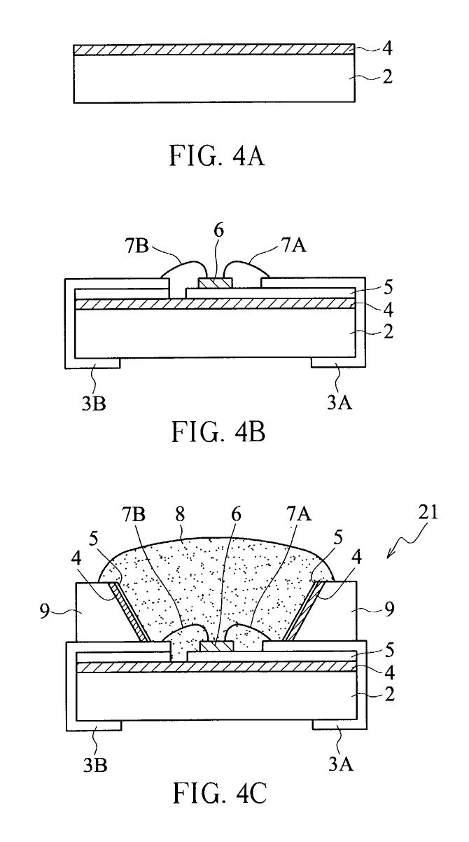

FIGS. 4A to 4C are sectional diagrams showing each step of the package method for enhancing the brightness of an LED according to still another embodiment of the invention.

First, as shown in FIG. 4A, a mount 2 with ceramic material is planarized. Next, as shown in FIG. 4B, after the opposed electrodes 3A and 3B formed by dipping, transfer printing, or blushing, the LED chip 6 can be attached to the mount 2, and the LED chip 6 will be electrically connected to electrodes 3A and 3B by wires 7A and 7B.

Then, as shown in FIG. 4C, the block member 9 are attached to the mount 2. The block member 9 have been planarized and deposited the metal reflection mirror 5 in advance, and the material of the block members can be ceramic, glass and other insulating materials. Finally, the resin 8 is used to cover the LED chip 6 and thereby the LED package 21 of the invention is completed.

Because the reflection mirror are formed on the mount 2 and block member 9, the surface of which has been planarized beforehand, they can similarly become a metal reflection mirror with high reflectivity to increase the total area of reflection so as to obtain the effect of enhancing the brightness. In addition, the block member 9 that have the metal reflection mirror formed on it can be allocated differently in accordance with the positions of the LED chip 6 and can be manufactured in different shapes. It is then easier to optimize the reflection mirror of the invention.

Also, the planarization of the invention can adopt a process that directly applies the method of chemical mechanical polishing on the mount 2 so that a smooth surface of the mount can be obtained.

The specific embodiments above are only intended to illustrate the invention; they does not, however, to limit the invention to the specific embodiments. Accordingly, various modifications and changes may be made without departing from the spirit and scope of the invention as described in the appended claims.

What is claimed is:

1. A package method for enhancing the brightness of an LED, comprising the following steps:
planarizing a surface of a mount;
forming a reflection mirror on the surface of the mount; and
attaching an LED chip to the mount.

2. The package method for enhancing the brightness of an LED as claimed in claim 1, wherein the mount is a ceramic substrate.

3. The package method for enhancing the brightness of an LED as claimed in claim 1, further comprising electrodes formed on the two ends of the mount.

4. The package method for enhancing the brightness of an LED as claimed in claim 3, wherein the electrodes are electrically connected to the LED chip.

5. The package method for enhancing the brightness of an LED as claimed in claim 1, wherein the planarization is completed by the method of transfer printing.

6. The package method for enhancing the brightness of an LED as claimed in claim 1, wherein the planarization is completed by the method of spraying or blushing.

7. The package method for enhancing the brightness of an LED as claimed in claim 1, wherein the planarization is completed by the method of dipping.

8. The package method for enhancing the brightness of an LED as claimed in claim 1, wherein the planarization is completed by the method of chemical mechanical polishing.

9. The package method for enhancing the brightness of an LED as claimed in claim 1, wherein the reflection mirror is formed by the method of metal sputtering.

10. The package method for enhancing the brightness of an LED as claimed in claim 1, wherein the reflection mirror is formed by the method of metal evaporation.

11. The package method for enhancing the brightness of an LED as claimed in claim 1, wherein the LED chip is attached to the mount by the method of surface mounting.

12. The package method for enhancing the brightness of an LED as claimed in claim 1, further including the step of sealing the LED chip with a resin.

13. The package method for enhancing the brightness of an LED as claimed in claim 1, wherein the mount forms with a recess.

14. The package method for enhancing the brightness of an LED as claimed in claim 13, wherein an extrusion is formed inside the recess of the mount.

15. The package method for enhancing the brightness of an LED as claimed in claim 14, wherein the LED chip is attached to the extrusion.

16. A package method for enhancing the brightness of an LED, including the following steps:
planarizing a surface of a mount;
forming electrodes on the surface of the mount and attaching an LED chip thereto; and
mounting a block member with a reflection mirror on the mount, wherein the reflection mirror forms on a surface of the block member that has been planarized.

17. The package method for enhancing the brightness of an LED as claimed in claim 15, wherein the block member is made of insulating materials.
